(19) United States
(12) Patent Application Publication
(10) Pub. No.: US 2016/0268276 A1
(43) Pub. Date: Sep. 15, 2016

(54) NONVOLATILE SEMICONDUCTOR MEMORY DEVICE AND METHOD OF MANUFACTURING THE SAME

(71) Applicant: Kabushiki Kaisha Toshiba, Minato-ku (JP)

(72) Inventor: Hiromitsu llNO, Nagoya (JP)

(73) Assignee: Kabushiki Kaisha Toshiba, Minato-ku (JP)

(21) Appl. No.: 14/803,233

(22) Filed: Jul. 20, 2015

Related U.S. Application Data
(60) Provisional application No. 62/132,255, filed on Mar. 12, 2015.

(51) Int. Cl. H01L 27/115

(52) U.S. Cl. CPC H01L 27/11556; H01L 27/11524; H01L 27/1157; H01L 27/11582

(57) ABSTRACT

According to one embodiment, a columnar semiconductor is arranged to extend in a vertical direction with respect to a substrate and have a bottom portion positioned inside the substrate. A first gate insulating layer including a charge storage layer is arranged on a side surface of the columnar semiconductor in a portion over a surface of the substrate. A laminated body is arranged surrounding the columnar semiconductor, with the first gate insulating layer intervening. The laminated body includes a conducting layer and an interlayer insulating layer laminated in alternation on the substrate. The columnar semiconductor has a lower end electrically coupled to the substrate under the surface of the substrate. The columnar semiconductor is also present under a lower end of the first gate insulating layer.

### CROSS REFERENCE TO RELATED APPLICATION

This application is based upon and claims the benefit of priority from U.S. Provisional Patent Application No. 62/132,255, filed on Mar. 12, 2015, the entire contents of which are incorporated herein by reference.

### FIELD

Embodiments described herein relate generally to a nonvolatile semiconductor memory device and a method of manufacturing the nonvolatile semiconductor memory device.

### BACKGROUND

Recently, in the field of NAND-type flash memories, attention has been focused on a laminated-type (three-dimensional) NAND-type flash memory as a device that can achieve high integration without being restricted by the limit of resolution of the lithography technology. This type of three-dimensional NAND-type flash memory includes a laminated body and a columnar semiconductor layer. In the laminated body, a plurality of conducting layers and interlayer insulating layers are laminated in alternation on a substrate. The conducting layers function as word lines and selection gate lines. The semiconductor layer is formed to pass through these laminated films. This semiconductor layer functions as a body of a memory string. Between the semiconductor layer and the conducting layer, a block insulating layer, a memory layer including a charge storage layer, and a tunnel insulating layer are sequentially formed.

In this three-dimensional NAND-type flash memory, the ON/OFF characteristics (selection characteristics) of selection transistors are important, and it is necessary to cause a flow of a sufficient cell current during selection.

### BRIEF DESCRIPTION OF THE DRAWINGS

FIG. 1 is a perspective view schematically illustrating one example of the structure of a nonvolatile semiconductor memory device 100 according to a first embodiment;

FIG. 2 is a perspective view illustrating the structure of a part of memory cell array 11;

FIG. 3 is an equivalent circuit diagram of one NAND cell unit NU;

FIG. 4 is a cross-sectional perspective view of one memory cell MC;

FIG. 5 is a plan view of a part of the memory cell array 11;

FIG. 6 is a cross-sectional view (a cross-sectional view along the X-X′ direction of FIG. 5) along the part of the memory cell array 11 in the Y direction;

FIG. 7 is a process diagram illustrating a method of manufacturing the memory cell MC;

FIG. 8 is a process diagram illustrating the method of manufacturing the memory cell MC;

FIG. 9 is a process diagram illustrating the method of manufacturing the memory cell MC;

FIG. 10 is a process diagram illustrating the method of manufacturing the memory cell MC;

FIG. 11 is a process diagram illustrating the method of manufacturing the memory cell MC;

FIG. 12 is a process diagram illustrating the method of manufacturing the memory cell MC;

FIG. 13 is a process diagram illustrating the method of manufacturing the memory cell MC;

FIG. 14 is a process diagram illustrating the method of manufacturing the memory cell MC;

FIG. 15 is a process diagram illustrating the method of manufacturing the memory cell MC;

FIG. 16 is a process diagram illustrating the method of manufacturing the memory cell MC;

FIG. 17 is a process diagram illustrating the method of manufacturing the memory cell MC;

FIG. 18 is a process diagram illustrating the method of manufacturing the memory cell MC; and

FIG. 19 is a diagram illustrating a comparative embodiment.

### DETAILED DESCRIPTION

A nonvolatile semiconductor memory device according to embodiments described below includes a memory cell array and a wiring portion. The memory cell array includes: a memory string where a plurality of memory cells is series-coupled together; and selection transistors coupled to one end of the memory string. The wiring portion is formed by laminating a conducting layer and an interlayer insulating layer in alternation on a substrate over a plurality of layers. The conducting layers function as gate electrodes for the memory cells and the selection transistors. One of the selection transistors includes a plurality of the conducting layers, and the plurality of the conducting layers are coupled in common to a common contact.

The following describes nonvolatile semiconductor memory devices according to embodiments in detail with reference to the accompanying drawings. Here, these embodiments are only examples, and are not described for the purpose of limiting the present invention. The respective drawings of the nonvolatile semiconductor memory devices used in the following embodiments are schematically illustrated. The thickness, the width, the ratio, and similar parameter of the layer are different from actual parameters.

The following embodiments relate to a nonvolatile semiconductor memory device in a structure where a plurality of metal-oxide-nitride-oxide-semiconductor (MONOS) type memory cells (transistors) is disposed in a height direction. The MONOS type memory cell includes: a semiconductor layer disposed in a columnar shape vertical to the substrate as a channel, and a gate electrode layer disposed on the side surface of the semiconductor layer via a charge storage layer. However, this is not also intended to limit the present invention. The present invention is applicable to another type of charge storage layer, for example, a semiconductor-oxide-nitride-oxide-semiconductor type (SONOS) memory cell or a floating-gate type memory cell.

### First Embodiment

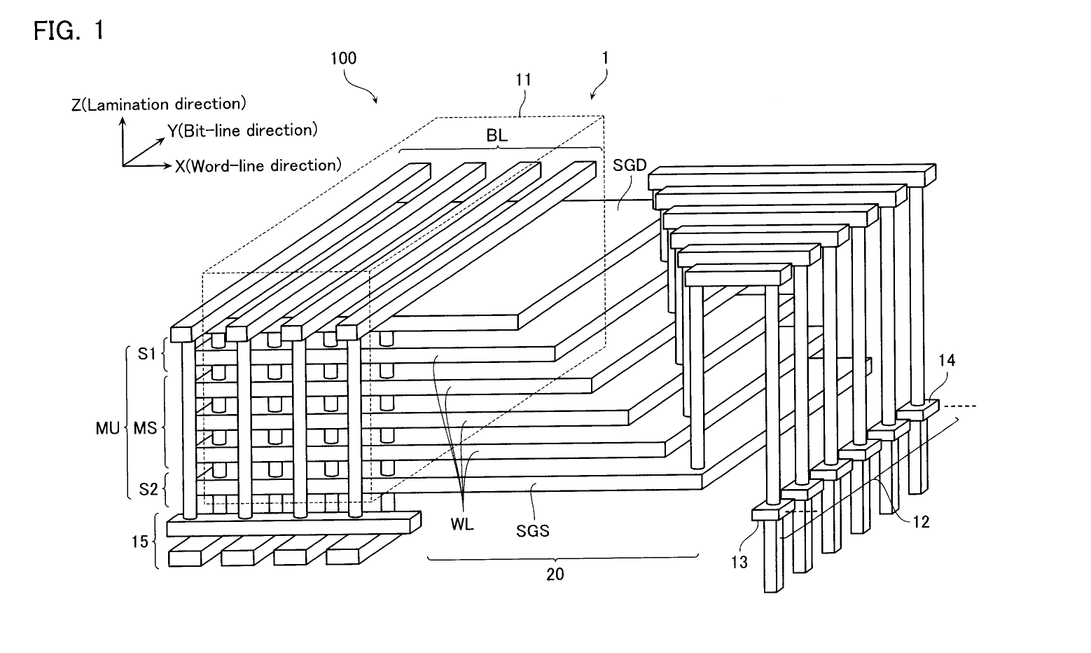

FIG. 1 is a perspective view schematically illustrating one example of the structure of a nonvolatile semiconductor memory device 100 of a first embodiment. The nonvolatile semiconductor memory device 100 includes a memory cell array 11, word-line driving circuits 12, a source-side selection-gate-line driving circuit 13, a drain-side selection-gate-line driving circuit 14, sense amplifiers 15, word lines WL, a source-side selection gate line SGS, a drain-side selection gate line SGD, bit lines BL, a word-line wiring portion, and similar portion.

The memory cell array 11 includes memory strings MS, drain-side selection transistors S1, and source-side selection transistors S2 on a semiconductor substrate (not illustrated in FIG. 1). The memory string MS is constituted such that a plurality of memory cells MC (memory transistors) are coupled together in series. The respective drain-side selection transistor S1 and source-side selection transistor S2 are coupled to both ends of the memory string MS. Here, the memory string MS, and the drain-side selection transistor S1 and the source-side selection transistor S2 coupled to both ends of the memory string MS are hereinafter referred to as a “NAND cell unit NU.”

As described later, the memory cell MC has the structure where a control gate electrode (word line) is disposed on the side surface of a columnar semiconductor film to be a channel via a memory layer including a charge storage layer. The drain-side selection transistor and the source-side selection transistor each have the structure where a selection gate electrode (selection gate line) is disposed on the side surface of a columnar semiconductor film via the memory layer including a charge storage layer. For simplification of the illustration, FIG. 1 illustrates the case where four memory cells MC are disposed in one memory string MS as the example. Obviously, the number of the memory cells MC in one memory string MS is not limited to this.

The word line WL is coupled in common to the adjacent memory cells along the X direction (the word-line direction) in FIG. 1. The source-side selection gate line SGS is coupled in common to the adjacent source-side selection transistors S2 along the word-line direction. The drain-side selection gate line SGD is coupled in common to the adjacent drain-side selection transistors S1 along the word-line direction. Here, in the following description, the source-side selection gate line SGS and the drain-side selection gate line SGD are collectively referred to simply as “selection gate lines” in some cases. The source-side selection transistor and the drain-side selection transistor are collectively referred to simply as “selection transistors” in some cases. Here, in the memory cells MC in the memory string MS, one or a plurality of the memory cells MC close to the source-side selection gate line SGS and the drain-side selection gate line SGD might be treated as a dummy cell that is not used for data storage. Also in the example described as follows, a description will be given of the example where one dummy cell is disposed at each of both ends of the memory string MS. This, however, should not be construed in a limiting sense. Two or more dummy cells may be disposed or the dummy cell may be omitted.

Furthermore, the bit lines BL are disposed to extend having the longitudinal direction in the Y direction (the bit-line direction) intersecting with the X direction (the word-line direction), and are collocated at a predetermined pitch in the X direction. The bit line BL is coupled to a plurality of the memory strings MS via the drain-side selection transistors S1. Source lines SL, which are omitted in FIG. 1, are disposed having the longitudinal direction, for example, in the Y direction and coupled to the memory strings MS via the source-side selection transistors S2.

The word-line driving circuit 12 is a circuit that controls the voltage to be applied to the word line WL. The source-side selection-gate-line driving circuit 13 is a circuit that controls the voltage to be applied to the source-side selection gate line SGS. The drain-side selection-gate-line driving circuit 14 is a circuit that controls the voltage to be applied to the drain-side selection gate line SGD. The sense amplifier 15 is a circuit for amplifying a signal (voltage) read out from a selected memory cell to the bit line BL.

A wiring portion 20 is a wiring portion for coupling the word lines WL and the selection gate lines SGD and SGS to the contacts. The word lines WL, the selection gate lines SGS and SGD have a structure processed in a staircase pattern such that the respective upper portions can independently be coupled to the contacts.

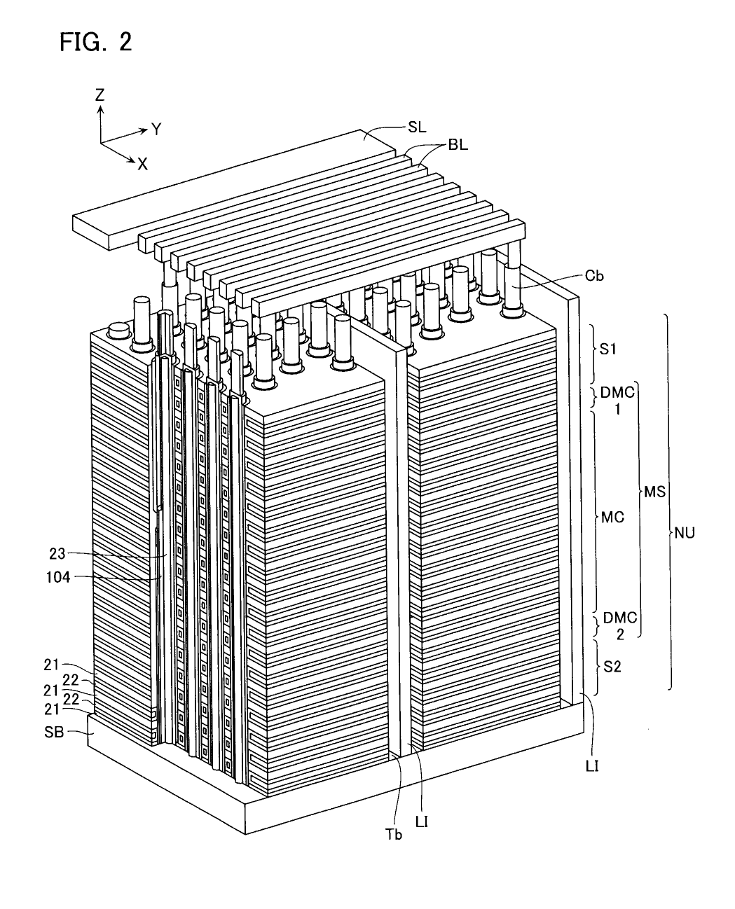

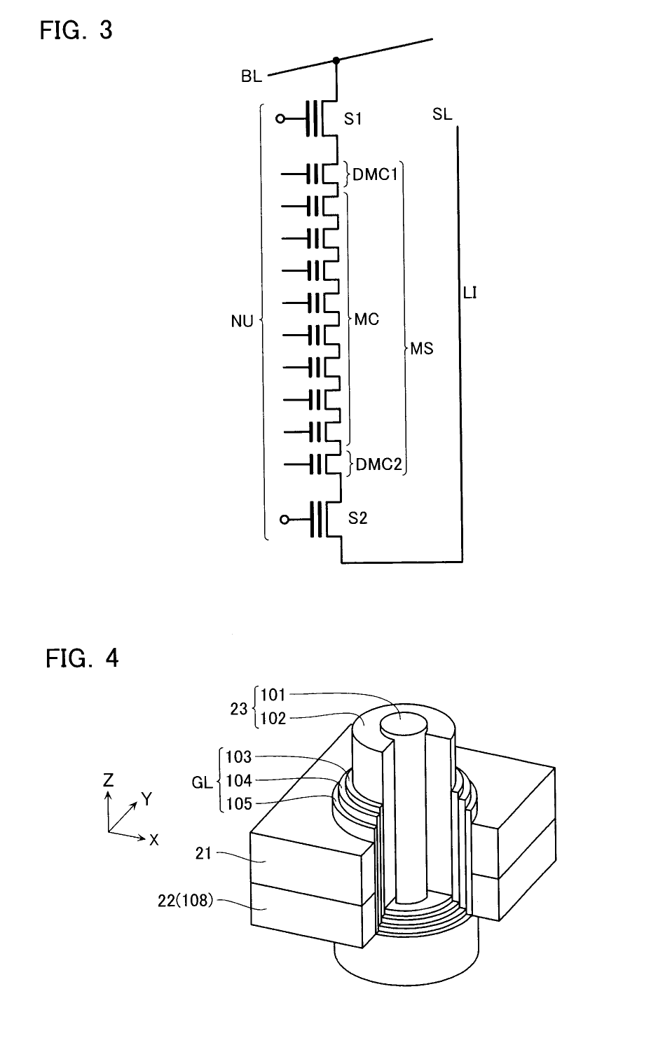

The following describes the detail of the structure of the memory cell array 11 with reference to FIG. 2 to FIG. 4. FIG. 2 is a perspective view illustrating the structure of a part of the memory cell array 11. FIG. 3 is an equivalent circuit diagram of one NAND cell unit NU. FIG. 4 is a cross-sectional perspective view of one memory cell MC and similar member.

As illustrated in FIG. 2, the memory cell array 11 has the structure where interlayer insulating layers 21 and conducting layers 22 are laminated in alternation on a semiconductor substrate SB. These conducting layers 22 function as the control gate (word line WL) of the memory cell MC, the source-side selection gate line SGS, and the drain-side selection gate line SGD. The interlayer insulating layers 21 are disposed in the above-and-below direction of these conducting layers 22 and electrically insulate the conducting layers 22 from one another.

The conducting layer 22 can be formed of, for example, tungsten (W), tungsten nitride (WN), tungsten silicide (WSix), tantalum (Ta), tantalum nitride (TaN), tantalum silicide (TaSix), palladium silicide (PdSix), erbium silicide (ErSix), yttrium silicide (YSix), platinum silicide (PtSix), hafnium silicide (HfSix), nickel silicide (NiSix), cobalt silicide (CoSix), titanium silicide (TiSix), vanadium silicide (VSix), chrome silicide (CrSix), manganese silicide (MnSix), iron silicide (FeSix), ruthenium (Ru), molybdenum (Mo), titanium (Ti), titanium nitride (TiN), vanadium (V), chrome (Cr), manganese (Mn), iron (Fe), cobalt (Co), nickel (Ni), gold (Au), silver (Ag) or copper (Cu), or can be formed of a compound of these materials. The conducting layer 22 may be formed of polysilicon with the addition of impurities.

To pass through this laminated body of the interlayer insulating layers 21 and the conducting layers 22, semiconductor layers 23 having the longitudinal direction in the lamination direction (the Z direction in FIG. 2) are collocated at a predetermined pitch in the XY plane. Between: the semiconductor layer 23; and the laminated body of the conducting layers 22 and the interlayer insulating layers 21, a memory layer 104 including a charge storage layer is formed. The memory layer 104 can be formed by a laminated structure of: a charge storage layer such as a silicon nitride film, and an oxide film such as a silicon oxide film. Depending on the storage amount of the electric charge to this charge storage layer, the threshold voltage of the memory cell MC changes. The memory cell MC holds the data corresponding to this threshold voltage.

The semiconductor layers 23 function as the channel regions (bodies) of the memory cells MC, the dummy cells DMC1 and DMC2, and the selection transistors S1 and S2 that are included in the NAND cell unit NU. These semiconductor layers 23 are coupled, on their upper ends, to the bit lines BL via contacts Cb. The bit lines BL having the longitudinal direction in the Y direction are collocated at a predetermined pitch along the X direction.

The lower end of the semiconductor layer 23 is electrically coupled to the substrate SB. As described later, the lower end of the semiconductor layer 23 is coupled to the source line SL via this semiconductor substrate SB and a source contact LI, which is described later. The source lines SL having the longitudinal direction in the Y direction are collocated, similarly to the bit lines BL.

Here, the laminated body of the interlayer insulating layers 21 and the conducting layers 22 in the memory cell array 11 is separated by blocks as the smallest unit of data erasure. At the boundary of the separation, a trench Tb is formed. In this trench Tb, an interlayer insulating layer (not illustrated) is implanted. Further, the source contact LI described above is formed passing through the interlayer insulating layer. This source contact LI has a lower end coupled to the semiconductor substrate SB while having an upper end coupled to the source line SL.

FIG. 3 is an equivalent circuit diagram of one NAND cell unit NU. In this memory cell array 11, the one NAND cell unit includes the memory string MS, the drain-side selection transistor S1, and the source-side selection transistor S2. The memory string MS is constituted of a plurality of the memory cells MC and dummy cells DMC1 and DMC2. The drain-side selection transistor S1 is coupled between the upper end of the memory string MS and the bit line BL. The source-side selection transistor S2 is coupled between the lower end of the memory string MS and the source line SL.

FIG. 4 illustrates one example of a specific structure of one of the memory cell MC and the dummy cell DMC. The semiconductor layer 23 in a columnar shape includes an oxide-film core 101 and a semiconductor portion (semiconductor columnar portion) 102 in a columnar shape, which surrounds the peripheral area of the oxide-film core 101. The oxide-film core 101 is formed of, for example, a silicon oxide film (SiO₂). The semiconductor columnar portion 102 is formed of, for example, silicon (Si), silicon-germanium (SiGe), silicon carbide (SiC), germanium (Ge), or carbon (C), and can be formed of a single layer or two layers.

In the peripheral area of this semiconductor columnar portion 102, a tunnel insulating layer 103, the memory layer 104 including the charge storage layer, and a block insulating layer 105 are arranged to surround the semiconductor columnar portion 102. The tunnel insulating layer 103 is formed of for example, a silicon oxide film (SiOx), and functions as the tunnel insulating layer of the memory cell MC or the dummy cell DMC. The memory layer 104 includes a charge storage layer made of, for example, a silicon nitride film (SiN), and has a function that traps electrons injected from the semiconductor columnar portion 102 via the tunnel insulating layer 103 by a write operation. The block insulating layer 105 can be formed of, for example, a silicon oxide film.

The tunnel insulating layer 103, the memory layer 104, and the block insulating layer 105 described above are collectively referred to as a gate insulating layer GL. In the case of FIG. 4, the gate insulating layer GL is constituted by three layers. However, the gate insulating layer GL can employ various structures with different number, order, materials, or similar parameter of the layers, but includes at least the charge storage layer described above.

Here, the materials of the tunnel insulating layer 103 and the block insulating layer 105 can employ, for example, Al₂O₃, Y₂O₃, La₂O₃, Gd₂O₃, Ce₂O₃, CeO₂, Ta₂O₅, HfO₂, ZrO₂, TiO₂, HfSiO, HfAlO, ZrSiO, ZrAlO, and AlSiO other than the silicon oxide film (SiOx).

In this example, the tunnel insulating layer 103, the memory layer 104, and the block insulating layer 105 are illustrated to be arranged in the whole region of the side surface of the semiconductor columnar portion 102. This, however, should not be construed in a limiting sense. These members can be arranged only on the side surface of the word line WL.

In the peripheral area of the semiconductor columnar portion 102, the interlayer insulating layer 21 described above and a tungsten electrode 108, which functions as the conductive layer 22, are laminated in alternation via the tunnel insulating layer 103, the memory layer 104, and the block insulating layer 105 to surround the semiconductor layer 23.

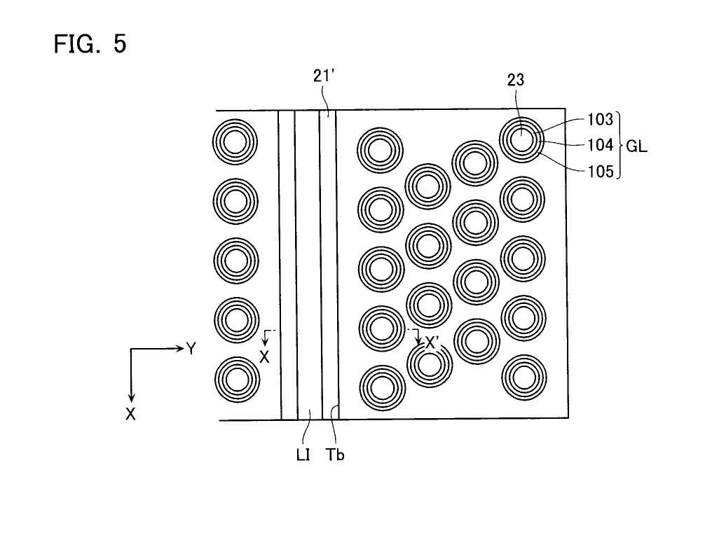

Regarding these memory cells MC, as illustrated in FIG. 5, which is a plan view of a part of the memory cell array 11, the semiconductor layers 23 (the semiconductor columnar portion 102) are arrayed in one row in the oblique direction with respect to the X direction (the word-line direction) and the Y direction (the bit-line direction). This increases the array density of the semiconductor layer 23, thus increasing the array density of the memory cell MC. However, this is only one example, and the semiconductor layers 23 can be disposed along the X direction and the Y direction. The source contact LI is formed in a stripe shape to have the longitudinal direction in the X direction, and is implanted in the trench Tb via an interlayer insulating layer 21′.

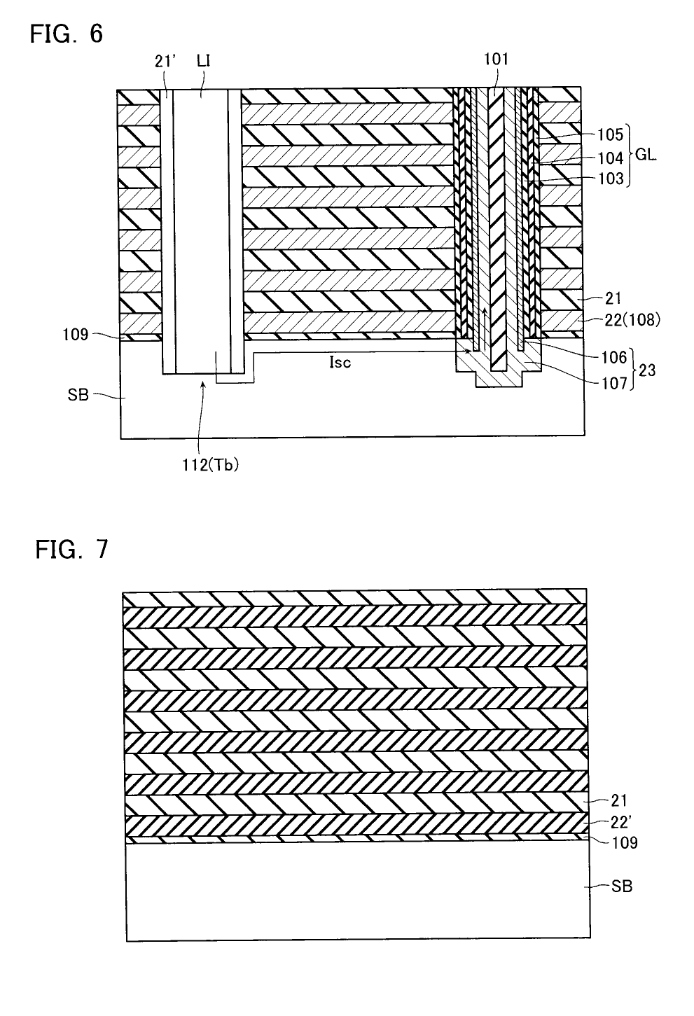

FIG. 6 is an X-X′ cross-sectional view of FIG. 5, and a cross-sectional view including the memory cell MC and the source contact LI. On the semiconductor substrate SB having the surface where a gate insulating layer 109 is arranged, the semiconductor layer 23 is arranged to extend in the vertical direction with respect to the substrate SB and have the bottom portion positioned inside the substrate SB. On the side surface of the semiconductor layer 23, in the portion over the surface of the substrate SB, the tunnel insulating layer 103, the memory layer 104 including the charge storage layer, and the block insulating layer 105 are sequentially formed. Furthermore, in the peripheral area of the semiconductor layer 23, the laminated body where the conducting layers 22 and the interlayer insulating layers 21 are laminated in alternation is arranged via the tunnel insulating layer 103, the memory layer 104, and the block insulating layer 105. The semiconductor layer 23 has the lower end electrically coupled to the substrate SB.

The semiconductor layer 23 includes a first semiconductor layer 106, which is arranged at the inner side of the tunnel insulating layer 103, and a second semiconductor layer 107, which is arranged at the inner side of the first semiconductor layer 106. The lower end of this first semiconductor layer 106 is positioned under the respective lower ends of the tunnel insulating layer 103, the memory layer 104, and the block insulating layer 105 described above. In other words, the first semiconductor layer 106 projects under the respective lower ends of the respective layers described above. At the inner side of the columnar semiconductor layer 23, the oxide-film core 101 is arranged. The above-described source contact LI is implanted in the trench Tb, which divides the memory cell array 11 by blocks, via the interlayer insulating layer 21′. The semiconductor layer 23 and the source contact LI are arranged in contact with the diffusion layer (not illustrated), which is arranged on the surface of the substrate SB, but are actually arranged such that their lower ends are positioned inside the substrate SB as illustrated in FIG. 6 due to slight difference in manufacturing. The semiconductor layer 23 illustrated in FIG. 6 has a diameter identical to the inner diameter of the gate insulating layer GL over the surface of the substrate SB, has a diameter identical to the outer diameter of the gate insulating layer GL under the substrate SB, and has a diameter identical to the inner diameter of the gate insulating layer GL in a further downward position.

In other words, the semiconductor layer 23 has a large diameter in the portion immediately below the surface of the substrate SB compared with the diameter in the portion over the surface of the substrate SB. Furthermore, the diameter in the bottom portion of the semiconductor layer 23 is smaller than the diameter in the portion immediately below the surface of the substrate SB. Here, the diameter in the portion over the surface of the substrate SB is approximately identical to the diameter in the bottom portion.

In FIG. 6, an arrow Isc indicates the path of the cell current flowing to the semiconductor layer 23, which is the channel, through the source contact LI and the substrate SB. In this embodiment, because the respective lower ends of the tunnel insulating layer 103, the memory layer 104 including the charge storage layer, and the block insulating layer 105 are arranged not to be positioned under the surface of the substrate SB, the cell current flows in a shortest path so as to prevent the deterioration of the cell current. As apparent from the above-described description, the tunnel insulating layer 103, the memory layer 104, and the block insulating layer 105 are not limited to the case where the respective lower ends are positioned on the identical plane to the surface of the substrate SB like FIG. 6, and may be arranged such that the respective lower ends are positioned on the side surface of the gate insulating layer 109, which is arranged on the surface of the substrate SB. The respective lower ends may be positioned under the surface of the substrate SB. Also in the case where the respective lower ends ae positioned under the surface of the substrate SB, the cell current Isc flows through the semiconductor layer 23 positioned under the substrate SB. This shortens the current path so as to allow improving the cell characteristics.

Here, in FIG. 6, the positions of the lower ends of the tunnel insulating layer 103, the memory layer 104, and the block insulating layer 105 are identical to one another. However, these positions may be different from one another.

### [Method of Manufacturing Memory Cell MC]

The following describes a method of manufacturing the memory cell MC with reference to FIG. 7 to FIG. 15.

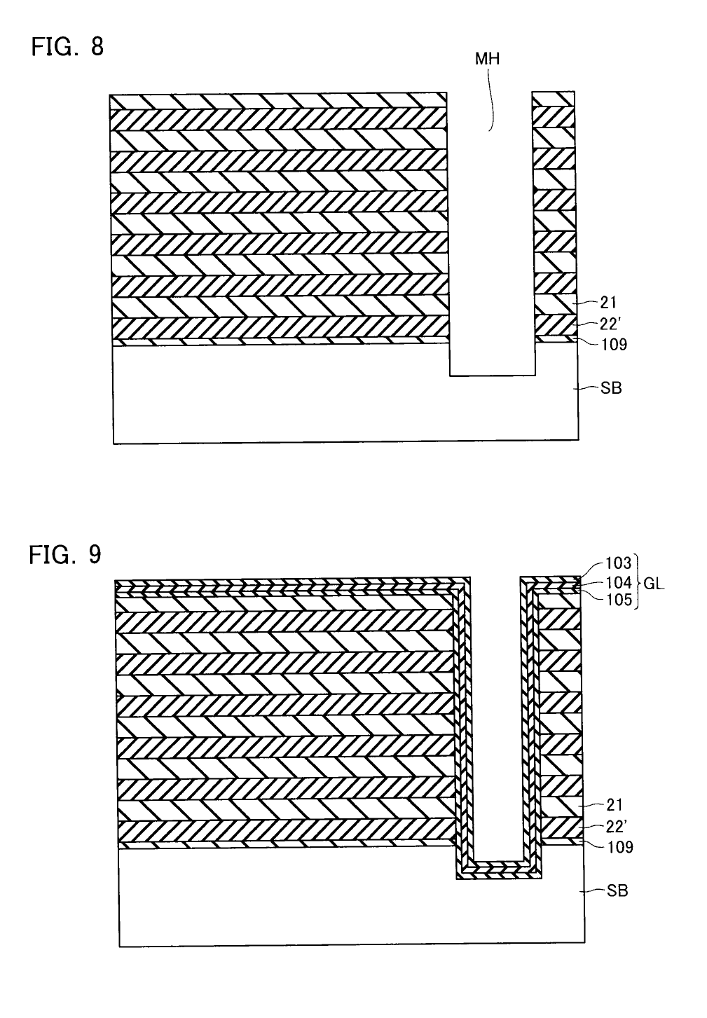

Firstly, as illustrated in FIG. 7, the gate insulating layer 109, which is formed of a silicon oxide film or similar film, is formed on the substrate SB, which is made of silicon or similar material. Then, a sacrifice film 22′, which is formed of a silicon nitride film, and the interlayer insulating layer 21, which is formed of, for example, a silicon oxide film, are laminated in alternation to form a laminated body. Subsequently, as illustrated in FIG. 8, a memory hole MH, which passes through the laminated body and the gate insulating layer 109, is formed by etching such as RIE. At the time of formation of this memory hole MH, when the memory hole MH is formed to have the bottom surface positioned above the surface of the substrate SB, it becomes impossible to ensure the conduction between the semiconductor layer, which is formed within the memory hole MH, and the substrate SB. This might cause deterioration in cell characteristics. Therefore, as illustrated in FIG. 8, the bottom portion of the memory hole MH is formed to be positioned under the surface of the substrate SB. That is, the memory hole MH is formed by etching not only the laminated body of the interlayer insulating layers 21 and the sacrifice films 22′ and the gate insulating layer 109, but also the substrate SB during etching.

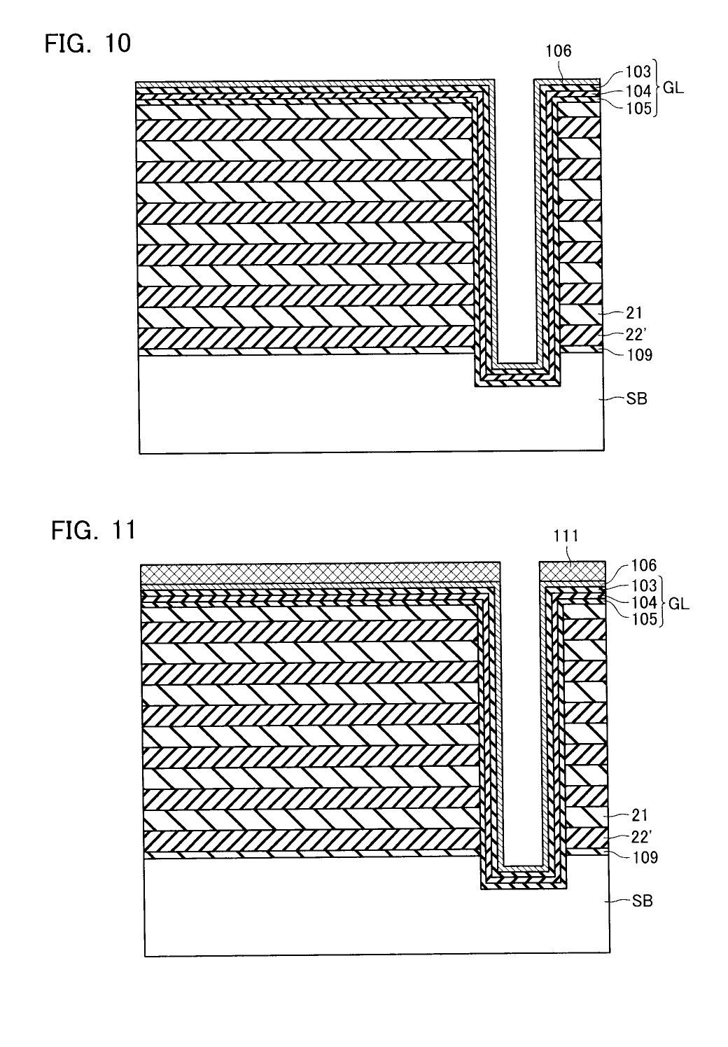

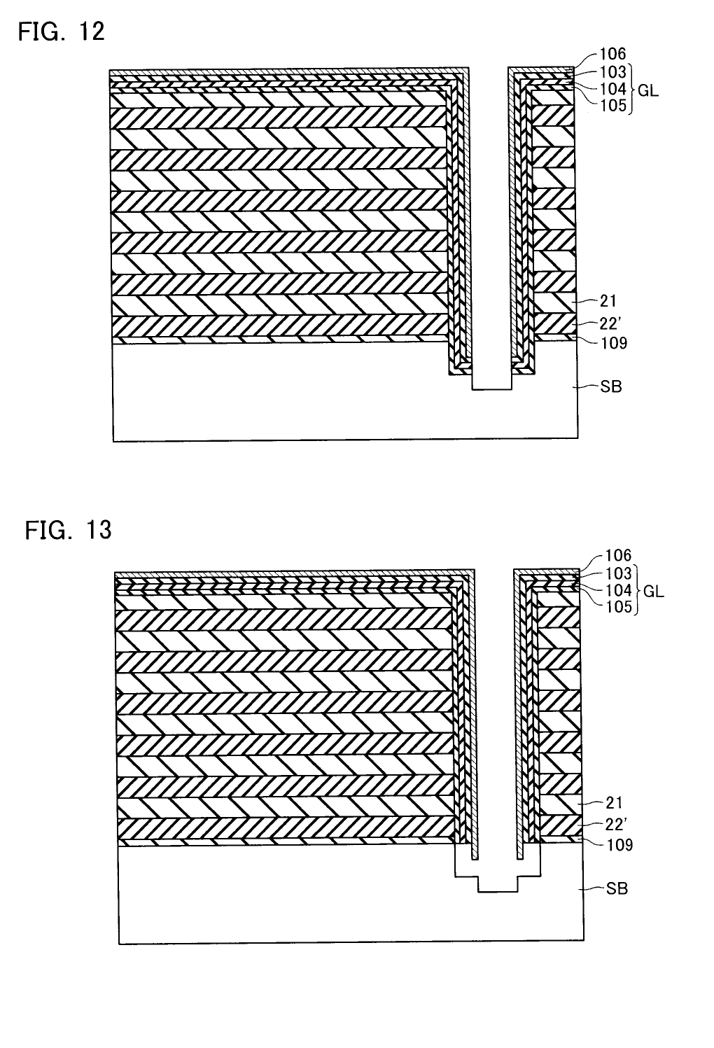

Subsequently, as illustrated in FIG. 9, the block insulating layer 105, the memory layer 104, and the tunnel insulating layer 103 are deposited on the inner wall of the memory hole MH using a CVD method or similar method. Further, as illustrated in FIG. 10, at the inner side of the tunnel insulating layer 103, the first semiconductor layer 106 made of, for example, non-doped silicon is formed. The materials of the block insulating layer 105, the memory layer 104, and the tunnel insulating layer 103 included in the memory gate insulating layer GL can preferably employ the above-described materials. Then, as illustrated in FIG. 11, a mask material 111 is formed as a film to cover the first semiconductor layer 106 formed in the region other than the inside of the memory hole MH. Subsequently, as illustrated in FIG. 12, the first semiconductor layer 106, the block insulating layer 105, the memory layer 104, and the tunnel insulating layer 103, which are present on the bottom surface of the memory hole MH, are removed by a method such as RIE. Also at this time, to reliably remove the respective layers present on the bottom surface of the memory hole MH, similarly to the case described using FIG. 8, the substrate SB is also etched at the same time.

After the films in the bottom portion of the memory hole MH are removed, only the portions present between the bottom portion of the memory hole MH and the surface of the substrate SB in the block insulating layer 105, the memory layer 104, and the tunnel insulating layer 103 inside the memory hole MH are removed as illustrated in FIG. 13. The method of this removal can employ a known dry etching or a wet etching. To remove the silicon oxide film, a hydrogen fluoride solution or similar solution is available. To remove the silicon nitride film, a phosphoric acid solution or similar solution is available.

Then, after the block insulating layer 105, the memory layer 104, and the tunnel insulating layer 103 inside the memory hole MH are removed, as illustrated in FIG. 14, the second semiconductor layer 107 is formed in a columnar shape to fill the void caused by removing the respective layers. Accordingly, the semiconductor layer 23 is present under the lower ends of the block insulating layer 105, the memory layer 104, and the tunnel insulating layer 103. Additionally, the contact, that is, the electrical coupling is formed between the semiconductor layer 23, which is formed in the bottom portion of the memory hole MH, and the substrate SB. Here, the second semiconductor layer 107 is also made of, for example, non-doped silicon.

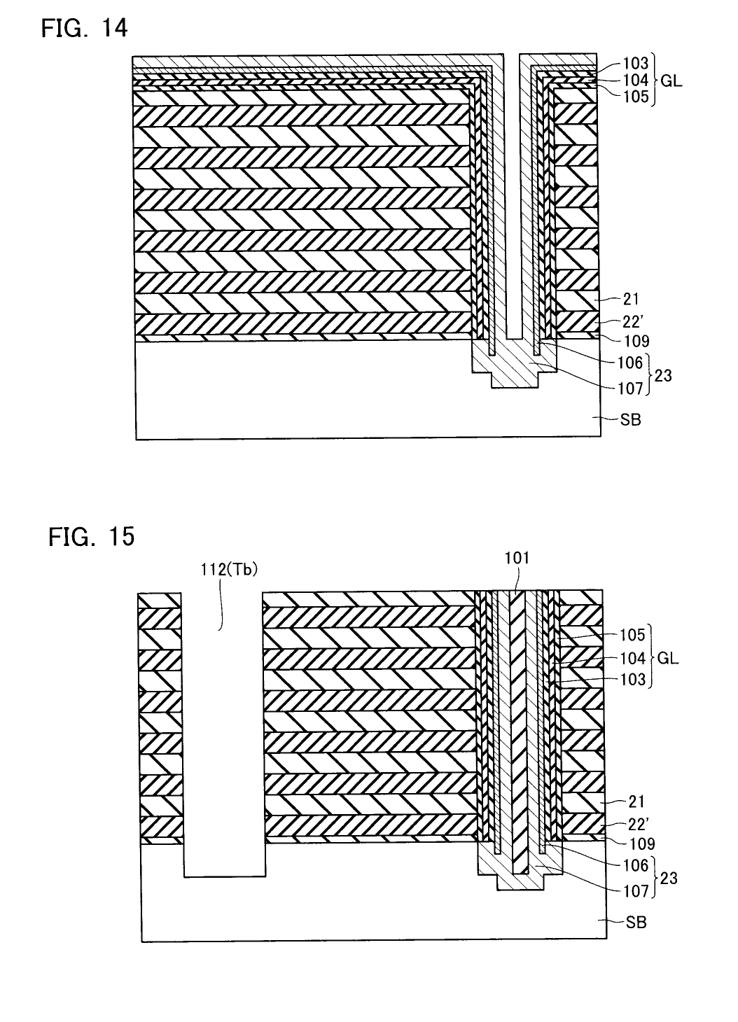

Lastly, as illustrated in FIG. 15, the oxide-film core 101 is formed at the inner side of the second semiconductor layer 107 in a columnar shape. Subsequently, a through-hole 112 is formed for forming the source contact LI. Then, the sacrifice films 22′ of the laminated body is replaced by metal layers as the conducting layers 22, using wet etching, dry etching or similar method. The interlayer insulating layer 21′ is deposited on the side surface of the through-hole 112 of the laminated body. Subsequently, a metal film made of tungsten or similar material is implanted to fill the through-hole 112, so as to form the source contact LI. Thus, the structure in FIG. 6 is completed.

### (Effect)

As described above, the first embodiment allows obtaining a nonvolatile semiconductor memory device having a three-dimensional structure that does not cause deterioration in cell current and thus does not cause deterioration in cell characteristics. Additionally, the semiconductor layer 23 is formed reaching the inside of the substrate SB. Accordingly, the substrate and the insulating film are hardly in contact with each other. This allows preventing an increase in contact resistance.

### Second Embodiment

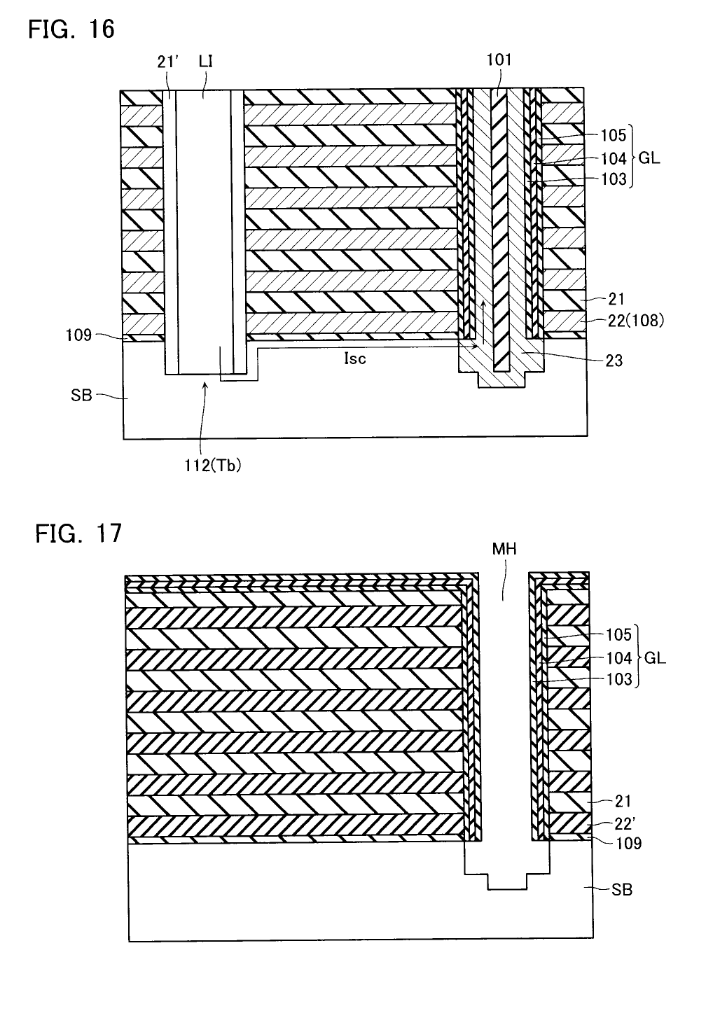

The following describes a nonvolatile semiconductor memory device according to a second embodiment with reference to FIG. 16 to FIG. 18. The overall configuration of this second embodiment is approximately identical to that of the first embodiment (in FIG. 6 to FIG. 15). However, this second embodiment differs from the first embodiment in the configuration of the semiconductor layer 23.

FIG. 16 is a cross-sectional view of the portion including the memory cell MC and the source contact LI in the nonvolatile semiconductor memory device according to the second embodiment. In this second embodiment, unlike the first embodiment where the columnar semiconductor layer has the two-layer structure including the first semiconductor layer 106 and the second semiconductor layer 107, the columnar semiconductor layer 23 is formed in a single layer structure.

The method of manufacturing the nonvolatile semiconductor memory device according to this second embodiment is similar to that in the first embodiment from FIG. 7 to FIG. 12. That is, as illustrated in FIG. 12, the block insulating layer 105, the memory layer 104 including the charge storage layer, the tunnel insulating layer 103, and the cover film (the first semiconductor layer in the first embodiment) 106 are formed at the inner side of the memory hole MH. Afterward, the bottom portion of the memory hole MH is further etched. Subsequently, as illustrated in FIG. 17, the portions present between the bottom portion of the memory hole MH and the surface of the substrate SB of the block insulating layer 105, the memory layer 104, and the tunnel insulating layer 103 inside the memory hole MH; and the cover film 106 are removed. This removal of the cover film 106 can also employ well-known wet etching or dry etching, similarly to the other films.

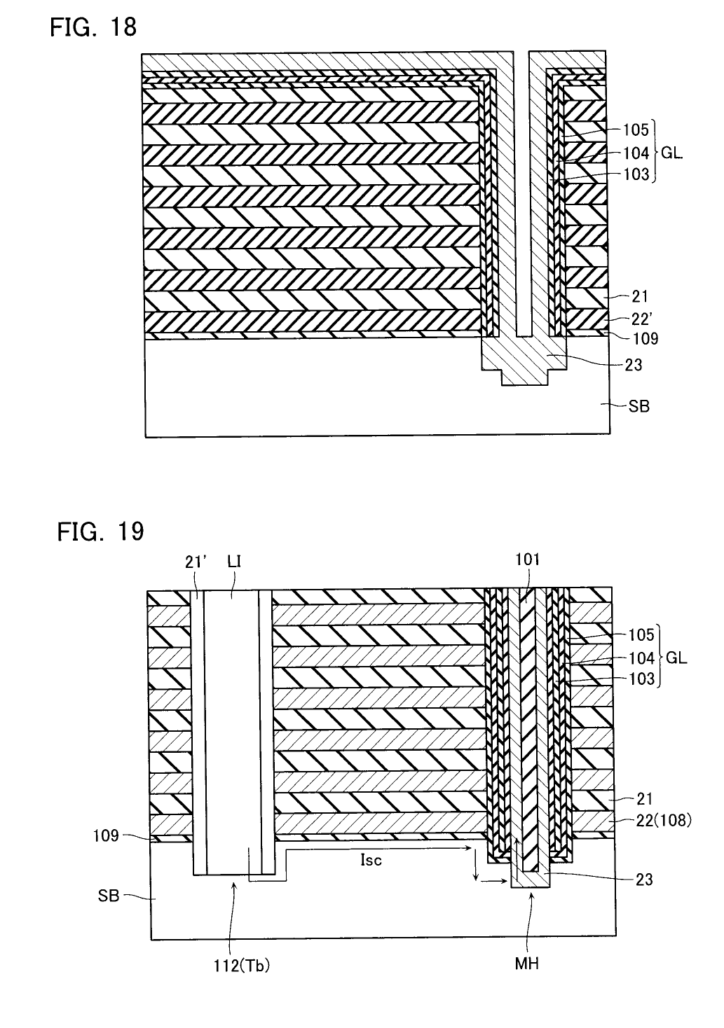

As illustrated in FIG. 18, the semiconductor layer 23 is formed in a columnar shape to fill the void caused by removing the films inside the memory hole MH. Lastly, similarly to the description of FIG. 15 in the first embodiment, the oxide-film core 101 is formed at the inner side of the semiconductor layer 23. Subsequently, the through-hole 112 is formed for forming the source contact LI. Then, the sacrifice films 22′ of the laminated body are replaced by metal layers as the conducting layers 22, using wet etching, dry etching, or similar method. The interlayer insulating layer 21′ is deposited on the side surface of the through-hole 112 of the laminated body. Subsequently, a metal film made of tungsten or similar material is implanted to fill the through-hole 112, so as to form the source contact LI. Thus, the structure in FIG. 16 is completed.

As just described, also in the second embodiment, the semiconductor layer 23 is present under the lower ends of the block insulating layer 105, the memory layer 104, and the tunnel insulating layer 103. Additionally, the contact, that is, the electrical coupling is formed between the semiconductor layer 23, which is formed in the bottom portion of the memory hole MH, and the substrate SB.

This second embodiment can also provide effects similar to those in the first embodiment. Furthermore, in the second embodiment, the semiconductor layer forming the columnar semiconductor layer is a single layer. This allows preventing separation of the channel, which is concerned in the first embodiment including the two-layered semiconductor layer, due to occurrence of a naturally oxidized film intervening in a two-layered semiconductor layer.

### [Charge Storage Layer]

As the material of the charge storage layer included in the memory layer 104, the silicon nitride film (SiN) is described in the above-described embodiment as an example. However, the following oxides can also be selected.
SiO₂, Al₂O₃, Y₂O₃, La₂O₃, Gd₂O₃, Ce₂O₃, CeO₂, Ta₂O₅, HfO₂, ZrO₂, TiO₂, HfSiO, HfAlO, ZrSiO, ZrAlO, and AlSiO
AB₂O₄ (However, A and B are identical or different elements, and, are one of Al, Sc, Ti, V, Cr, Mn, Fe, Co, Ni, Cu, Zn, Ga, and Ge. For example, Fe₃O₄, FeAl₂O₄, Mn₁₋ₓAl₂₋ₓO_{4+y}, Co_{1+X}Al₂₋ₓO_{4+y}, and MnOx are employed.)
ABO₃ (However, A and B are identical or different elements, and, are one of Al, La, Hf, Ta, W, Re, Os, Ir, Pt, Au, Hg, Tl, Pb, Bi, Ce, Pr, Nd, Pm, Sm, Eu, Gd, Tb, Dy, Ho, Er, Tm, Yb, Lu, Sc, Ti, V, Cr, Mn, Fe, Co, Ni, Cu, Zn, Ga, Ge, Y, Zr, Nb, Mo, Tc, Ru, Rh, Pd, Ag, Cd, In, and Sn. For example, LaAlO₃, SrHfO₃, SrZrO₃, and SrTiO₃ are employed.)

As the material of the charge storage layer, the following oxynitrides can also be selected.
SiON, AlON, YON, LaON, GdON, CeON, TaON, HfON, ZrON, TiON, LaAlON, SrHfON, SrZrON, SrTiON, HfSiON, HfAlON, ZrSiON, ZrAlON, and AlSiON

Further, it is also possible to employ the materials obtained by replacing a part of the oxygen elements of the oxides described above by nitrogen elements. In particular, one insulating layer and a plurality of insulating layers are each preferred to be selected from the group consisting of SiO₂, SiN, Si₃N₄, Al₂O₃, SiON, HfO₂, HfSiON, Ta₂O₅, TiO₂, and SrTiO₃

In particular, regarding silicon-based insulating films such as SiO₂, SiN, and SiON, the respective concentrations of the oxygen elements and the nitrogen elements can be set to be equal to or more than 1×10¹⁸ atoms/cm³. However, the barrier heights of the plurality of insulating layers are different from one another. The insulating layer can include a material including impurity atoms that forms a defect level or semiconductor/metal dots (the quantum dots).

### Comparative Embodiment

Lastly, a description will be given of a comparative embodiment using FIG. 19. In a nonvolatile semiconductor memory device according to the comparative embodiment, the respective lower ends of the block insulating layer 105, the memory layer 104 including the charge storage layer, and the tunnel insulating layer 103, which are formed inside the memory hole MH, are positioned inside the substrate SB. Accordingly, the cell current flowing to the memory cell MC from the source contact LI follows the path as indicated by the arrow Isc in FIG. 19. Therefore, in the nonvolatile semiconductor memory device according to the comparative embodiment, the path of the cell current becomes long and the value of voltage drop becomes large compared with the first and second embodiments, so as to cause deterioration of the cell characteristics.

### [Others]

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor memory device, comprising:
a substrate;
a columnar semiconductor formed to extend in a vertical direction with respect to the substrate and have a bottom portion positioned inside the substrate;
a first gate insulating layer formed on a side surface of the columnar semiconductor, the first gate insulating layer including a charge storage layer; and
a laminated body formed surrounding the columnar semiconductor, with the first gate insulating layer intervening, the laminated body including a conducting layer and an interlayer insulating layer laminated in alternation on the substrate, wherein
the columnar semiconductor has a lower end electrically coupled to the substrate under a surface of the substrate, and
the columnar semiconductor is also present under a lower end of the first gate insulating layer.

2. The nonvolatile semiconductor memory device according to claim 1, wherein
the columnar semiconductor includes:
a first semiconductor layer arranged along the first gate insulating layer; and
a second semiconductor layer arranged to extend in a vertical direction with respect to the substrate and have a bottom portion positioned under the surface of the substrate, the second semiconductor layer being arranged on the first semiconductor layer over the surface of the substrate while being electrically coupled to the substrate under the surface of the substrate.

3. The nonvolatile semiconductor memory device according to claim 1, wherein
the substrate includes a second gate insulating layer formed on the substrate, and
the lower end of the first gate insulating layer is in contact with the columnar semiconductor on a side surface of the second gate insulating layer.

4. The nonvolatile semiconductor memory device according to claim 1, wherein
the substrate includes a second gate insulating layer formed on the substrate, and
the lower end of the first gate insulating layer is positioned under a lower end of the second gate insulating layer.

5. The nonvolatile semiconductor memory device according to claim 1, wherein
the columnar semiconductor includes:
a first portion having a diameter identical to an inner diameter of the first gate insulating layer; and
a second portion positioned under the first portion, the second portion having a diameter identical to an outer diameter of the first gate insulating layer.

6. The nonvolatile semiconductor memory device according to claim 5, wherein
the columnar semiconductor further includes a third portion positioned under the second portion, the third portion having a diameter identical to an inner diameter of the first gate insulating layer.

7. The nonvolatile semiconductor memory device according to claim 2, wherein
the lower end of the first semiconductor layer is positioned under the lower end of the first gate insulating layer.

8. The nonvolatile semiconductor memory device according to claim 2, wherein
the second semiconductor layer is directly in contact with each of the first semiconductor layer and the substrate.

9. The nonvolatile semiconductor memory device according to claim 1, wherein
the first gate insulating layer includes a tunnel insulating layer, a charge storage layer, and a block insulating layer, and
the columnar semiconductor is present at least under a lower end of the block insulating layer.

10. The nonvolatile semiconductor memory device according to claim 9, wherein
the columnar semiconductor is present under all lower ends of the tunnel insulating layer, the charge storage layer, and the block insulating layer.

11. The nonvolatile semiconductor memory device according to claim 1, wherein
the columnar semiconductor has a large diameter immediately below the surface of the substrate compared with a diameter over the surface of the substrate.

12. The nonvolatile semiconductor memory device according to claim 1, wherein
the columnar semiconductor has a small diameter in a bottom portion of the columnar semiconductor compared with a diameter immediately below the surface of the substrate.

13. A method of manufacturing a nonvolatile semiconductor memory device, comprising:
forming a laminated body by laminating a conducting layer and an interlayer insulating layer in alternation on a substrate;
forming a memory hole passing through the laminated body, the memory hole having a bottom surface positioned under a surface of the substrate;
forming a first gate insulating layer including a charge storage layer on an inner wall of the memory hole;
removing the first gate insulating layer on the bottom surface of the memory hole;
removing a portion present at least under the surface of the substrate in the first gate insulating layer; and
forming a columnar semiconductor along the inner wall of the memory hole, wherein
the columnar semiconductor is present along the first gate insulating layer over the surface of the substrate, electrically coupled to the substrate under the surface of the substrate, and also present under a lower end of the first gate insulating layer.

14. The method of manufacturing the nonvolatile semiconductor memory device according to claim 13, further comprising:
forming a first semiconductor layer along the first gate insulating layer after forming the first gate insulating layer;
removing the first gate insulating layer and the first semiconductor layer on the bottom surface of the memory hole; and
forming a second semiconductor layer on the first semiconductor layer over the surface of the substrate while the second semiconductor layer is electrically coupled to an inner sidewall of the memory hole under the surface of the substrate, after removing a portion of the first gate insulating layer present under the surface of the substrate.

15. The method of manufacturing the nonvolatile semiconductor memory device according to claim 13, wherein
the substrate includes a second gate insulating layer formed on the substrate, and
the lower end of the first gate insulating layer is in contact with the columnar semiconductor on a side surface of the second gate insulating layer.

16. The method of manufacturing the nonvolatile semiconductor memory device according to claim 13, wherein
the substrate includes a second gate insulating layer formed on the substrate, and
the lower end of the first gate insulating layer is positioned under a lower end of the second gate insulating layer.

17. The method of manufacturing the nonvolatile semiconductor memory device according to claim 13, wherein
the columnar semiconductor includes:
a first portion having a diameter identical to an inner diameter of the first gate insulating layer; and
a second portion positioned under the first portion, the second portion having a diameter identical to an outer diameter of the first gate insulating layer.

18. The method of manufacturing the nonvolatile semiconductor memory device according to claim 17, wherein
the columnar semiconductor further includes a third portion positioned under the second portion, the third portion having a diameter identical to an inner diameter of the first gate insulating layer.

19. The method of manufacturing the nonvolatile semiconductor memory device according to claim 14, wherein
the lower end of the first semiconductor layer is positioned under the lower end of the first gate insulating layer.

20. The method of manufacturing the nonvolatile semiconductor memory device according to claim 14, wherein
the second semiconductor layer is directly in contact with each of the first semiconductor layer and the substrate.
